(19) United States
(12) Patent Application Publication
(10) Pub. No.: US 2024/0387477 A1
(43) Pub. Date: Nov. 21, 2024

(54) DISPLAY DEVICE

(71) Applicant: Samsung Display Co., LTD., Yongin-si (KR)

(72) Inventors: Jin Woo CHOI, Yongin-si (KR); Dae Ho SONG, Yongin-si (KR); Hyung Il JEON, Yongin-si (KR)

(73) Assignee: Samsung Display Co., LTD., Yongin-si (KR)

(21) Appl. No.: 18/613,808

(22) Filed: Mar. 22, 2024

(30) Foreign Application Priority Data
May 16, 2023 (KR) 10-2023-0063262

(51) Int. Cl. H01L 25/075; H01L 33/50; H01L 33/54

(52) U.S. Cl. CPC H01L 25/0753; H01L 33/505; H01L 33/54

(57) ABSTRACT

A display device includes light emitting elements including a porous layer, a first protective layer disposed on the light emitting elements and including an opening exposing a side surface of the porous layer, and a second protective layer covering the opening of the first protective layer. The porous layer includes a color conversion material.

### CROSS REFERENCE TO RELATED APPLICATION(S)

This application claims priority to and benefits of Korean Patent Application No. 10-2023-0063262 under 35 U.S.C. § 119, filed on May 16, 2023, in the Korean Intellectual Property Office (KIPO), the entire contents of which are incorporated herein by reference.

### BACKGROUND

### 1. Technical Field

The disclosure relates to a light emitting display device.

### 2. Description of the Related Art

Recently, as interest in an information display is increasing, research and development for a display device are continuously being conducted.

### SUMMARY

The disclosure provides a display device with simple manufacturing process and improved light extraction efficiency.

An object of the disclosure is not limited to the above-described object, and other technical objects which are not described will be clearly understood by those skilled in the art from the following description.

According to an embodiment of the disclosure, a display device may include light emitting elements including a porous layer, a first protective layer disposed on the light emitting elements and including an opening exposing a side surface of the porous layer, and a second protective layer covering the opening of the first protective layer. The porous layer may include a color conversion material.

The light emitting elements may further include a first semiconductor layer, a second semiconductor layer, and an active layer disposed between the first semiconductor layer and the second semiconductor layer.

The porous layer and the second semiconductor layer may include a same material.

The porous layer may include a pore of a nano scale.

The color conversion material may be disposed in the pore.

The second protective layer may contact the porous layer exposed by the opening of the first protective layer.

The display device may further include an organic layer disposed between the light emitting elements.

The display device may further include a third protective layer disposed between the second protective layer and the organic layer.

The display device may further include an optical pattern layer disposed on the light emitting elements.

The optical pattern layer may be directly disposed on the porous layer.

According to an embodiment of the disclosure, a display device may include a first light emitting element, a second light emitting element, and a third light emitting element, each including a porous layer, a first protective layer disposed on the first to third light emitting elements and including a first opening exposing a side surface of the first light emitting element, and a second protective layer disposed on the first protective layer and including a second opening exposing a side surface of the second light emitting element. The porous layer of the first light emitting element may include a first color conversion material, and the porous layer of the second light emitting element may include a second color conversion material.

The second protective layer may contact the porous layer of the first light emitting element exposed by the first opening of the first protective layer.

The display device may further include a third protective layer disposed on the second protective layer.

The third protective layer may contact the porous layer of the second light emitting element exposed by the second opening of the second protective layer.

The display device may further include an organic layer disposed between the first to third light emitting elements.

The porous layer of the third light emitting element may include a scattering body.

Each of the first to third light emitting elements may further include a first semiconductor layer, a second semiconductor layer, and an active layer disposed between the first semiconductor layer and the second semiconductor layer.

The display device may further include an optical pattern layer disposed on the first to third light emitting elements.

The second semiconductor layer may be directly disposed on a first surface of the porous layer.

The optical pattern layer may be directly disposed on a second surface of the porous layer.

Details of other embodiments are included in the detailed description and drawings.

According to an embodiment of the disclosure, a manufacturing process may be simplified by injecting the color conversion material into the porous layer through the opening of the protective layer exposing the side surface of the porous layer, and light extraction efficiency may be improved by forming the optical pattern layer on the porous layer.

An effect of the disclosure is not limited by the contents illustrated above, and more various effects are included in the specification.

### BRIEF DESCRIPTION OF THE DRAWINGS

The above and other features of the disclosure will become more apparent by describing in further detail embodiments thereof with reference to the accompanying drawings, in which:

FIG. 1 is a plan view illustrating a display device according to an embodiment;

FIG. 2 is a schematic diagram of an equivalent circuit of a pixel according to an embodiment;

FIGS. 3 and 4 are schematic cross-sectional views illustrating a pixel according to an embodiment;

FIGS. 5 to 14 are schematic cross-sectional views for each process step of a method of manufacturing a display device according to an embodiment; and

FIGS. 15 to 18 are schematic cross-sectional views for each process step of a method of manufacturing a display device according to an embodiment.

### DETAILED DESCRIPTION OF THE EMBODIMENT

The advantages and features of the disclosure and a method of achieving them will become apparent with reference to the embodiments described in detail below together with the accompanying drawings. However, the disclosure is not limited to the embodiments disclosed below, and may be implemented in various different forms. The embodiments are provided so that the disclosure will be thorough and complete and those skilled in the art to which the disclosure pertains can fully understand the scope of the disclosure. The disclosure is only defined by the scope of the claims.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

The term used in the specification is for describing embodiments and is not intended to limit the disclosure. The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items. The same reference numerals denote to the same components throughout the specification.

Although a first, a second, and the like are used to describe various components, these components are not limited by these terms. These terms are used only to distinguish one component from another component. Therefore, a first component described below may be a second component within the technical spirit of the disclosure.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure are described in detail with reference to the accompanying drawings.

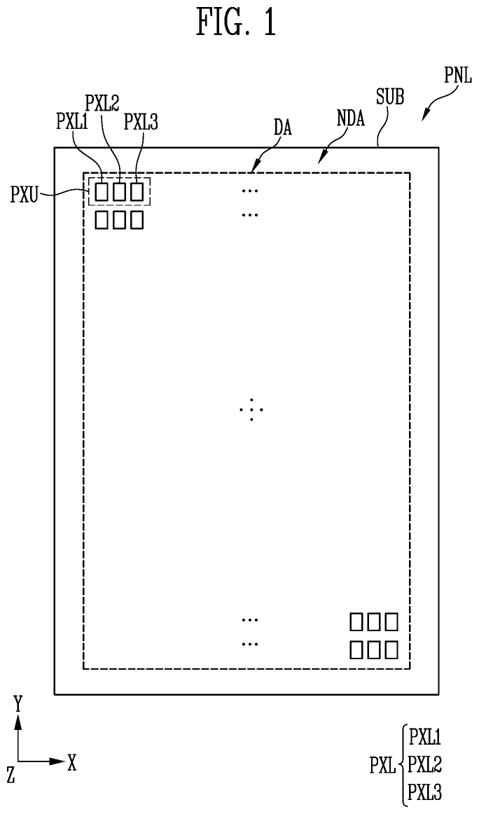

FIG. 1 is a plan view illustrating a display device according to an embodiment.

FIG. 1 illustrates a display device using a light emitting element as a light source, particularly, a display panel PNL included in the display device.

For convenience of description, in FIG. 1, a structure of the display panel PNL is schematically shown based on a display area DA. However, according to an embodiment, at least one driving circuit unit (for example, at least one of a scan driver and a data driver), lines, and/or pads, which are/is not shown, may be further disposed on the display panel PNL.

Referring to FIG. 1, the display panel PNL may include a substrate SUB and a pixel unit PXU disposed on the substrate SUB. The pixel unit PXU may include first pixels PXL1, second pixels PXL2, and/or third pixel PXL3. Hereinafter, in case that at least one of the first pixels PXL1, the second pixels PXL2, and the third pixels PXL3 is arbitrarily referred to, or in case that two or more types of pixels are collectively referred to, the at least one pixel or the two or more types of pixels may be referred to as a “pixel PXL” or “pixels PXL”.

The substrate SUB may configure a base member of the display panel PNL, and may be a rigid or flexible substrate or film. For example, the substrate SUB may be a rigid substrate formed of glass or tempered glass, or a flexible substrate (or thin film) of a plastic or a metal, but a material and/or physical properties of the substrate SUB are not particularly limited.

The display panel PNL and the substrate SUB for forming the display panel PNL may include a display area DA for displaying an image and a non-display area NDA other than the display area DA. The pixels PXL may be disposed in the display area DA. Various lines, pads, and/or built-in circuits connected to the pixels PXL of the display area NDA may be disposed in the non-display area NDA. The pixels PXL may be regularly arranged according to a stripe or PenTile™ arrangement structure, or the like. However, an arrangement structure of the pixels PXL is not necessarily limited thereto, and the pixels PXL may be arranged in the display area DA in various structures and/or methods.

According to an embodiment, two or more types of pixels PXL emitting light of different colors may be disposed in the display area DA. For example, in the display area DA, the first pixels PXL1 emitting light of a first color, the second pixels PXL2 emitting light of a second color, and the third pixel PXL3 emitting light of a third color may be arranged. At least one of the first to third pixels PXL1, PXL2, and PXL3 disposed adjacent to each other may configure one pixel unit PXU emitting light of various colors. For example, each of the first to third pixels PXL1, PXL2, and PXL3 may be a sub-pixel emitting light of a color (predetermined or selectable color). According to an embodiment, the first pixel PXL1 may be a red pixel emitting red light, the second pixel PXL2 may be a green pixel emitting green light, and the third pixel PXL3 may be a blue pixel emitting blue light, but the disclosure is not necessarily limited thereto.

In an embodiment, each of the first pixel PXL1, the second pixel PXL2, and the third pixel PXL3 may include light emitting elements that emit light of a same color, and may include a color conversion layer and/or a color filter of different colors disposed on the respective light emitting elements, to emit light of the first color, the second color, and the third color, respectively. In another embodiment, the first pixel PXL1, the second pixel PXL2, and the third pixel PXL3 may include a light emitting element of the first color, a light emitting element of the second color, and a light emitting element of the third color as a light source, to emit light of the first color, the second color, and the third color, respectively. However, the color, type, number, and/or the like of pixels PXL configuring pixel unit PXU are/is not particularly limited.

The pixel PXL may include at least one light source driven by a control signal (for example, a scan signal and a data signal) and/or power (for example, first power and second power). In an embodiment, the light source may include ultra-small column shape light emitting elements having a size as small as a nanometer scale to a micrometer scale. However, the disclosure is not necessarily limited thereto, and various types of light emitting elements may be used as a light source of the pixel PXL.

In an embodiment, each pixel PXL may be configured as an active pixel. However, a type, a structure, and/or a driving method of the pixels PXL applicable to the display device are/is not particularly limited. For example, each pixel PXL may be configured as a pixel of a passive or active light emitting display device of various structures and/or driving methods.

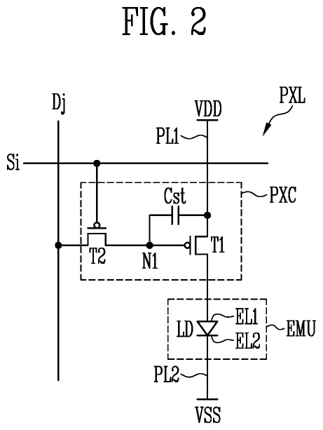

FIG. 2 is a schematic diagram of an equivalent circuit of a pixel according to an embodiment.

FIG. 2 schematically illustrates an electrical connection relationship between components included in the pixel PXL applicable to an active display device. However, a type of components included in the pixel PXL is not necessarily limited thereto.

According to an embodiment, the pixel PXL shown in FIG. 2 may be one of the first pixel PXL1, the second pixel PXL2, and the third pixel PXL3 provided in the display panel PNL of FIG. 1. The first pixel PXL1, the second pixel PXL2, and the third pixel PXL3 may have structures substantially identical or similar to each other.

Referring to FIG. 2, each pixel PXL may include a light emitting unit EMU that generates light of a luminance corresponding to a data signal. The pixel PXL may further include a pixel circuit PXC for driving the light emitting unit EMU.

According to an embodiment, the light emitting unit EMU may include at least one light emitting element LD connected between a first power line PL1 to which a voltage of first power VDD is applied and a second power line PL2 to which a voltage of the second power VSS is applied. For example, the light emitting unit EMU may include a first electrode EL1 connected to the first power VDD via the pixel circuit PXC and the first power line PL1, a second electrode EL2 connected to the second power VSS through the second power line PL2, and the light emitting element LD connected between the first electrode EL1 and the second electrode EL2. In an embodiment, the first electrode EL1 may be an anode electrode, and the second electrode EL2 may be a cathode electrode.

The light emitting element LD may include an end connected to the first power VDD and another end connected to the second power VSS. According to the embodiment, the end of the light emitting element LD may be integrally provided with the first electrode EL1 and connected to the first electrode EL1, and the another end of the light emitting element LD may be integrally provided with the second electrode EL2 and connected to the second electrode EL2. The first power VDD and the second power VSS may have different potentials. A potential difference between the first power VDD and the second power VSS may be set to be greater than or equal to a threshold voltage of the light emitting element LD during an emission period of the pixel PXL.

The light emitting element LD may configure an effective light source of the light emitting unit EMU. The light emitting element LD may emit light with a luminance corresponding to a driving current supplied through the pixel circuit PXC. For example, during each frame period, the pixel circuit PXC may supply a driving current corresponding to a grayscale value of corresponding frame data to the light emitting unit EMU. The driving current supplied to the light emitting unit EMU may flow through the light emitting element LD. Accordingly, the light emitting unit EMU may emit light while the light emitting element LD emits light with the luminance corresponding to the driving current.

The pixel circuit PXC may be connected to a scan line Si and a data line Dj of the pixel PXL. For example, in case that the pixel PXL is disposed in an i-th (i is a positive integer) row and a j-th (j is a positive integer) column of the display area DA, the pixel circuit PXC of the pixel PXL may be connected to the i-th scan line Si and the j-th data line Dj of the display area DA. According to an embodiment, the pixel circuit PXC may include first and second transistors T1 and T2 and a storage capacitor Cst. However, a structure of the pixel circuit PXC is not limited to the embodiment shown in FIG. 2.

The pixel circuit PXC may include the first and second transistors T1 and T2 and the storage capacitor Cst.

A first terminal of the first transistor (or driving transistor) T1 may be connected to the first power VDD, and a second terminal of the first transistor (or driving transistor) T1 may be electrically connected to the light emitting element LD. A gate electrode of the first transistor T1 may be connected to a first node N1. The first transistor T1 may control an amount of the driving current supplied to the light emitting element LD in response to a voltage of the first node N1.

A first terminal of the second transistor (or switching transistor) T2 may be connected to the j-th data line Dj, and a second terminal of the second transistor (or switching transistor) T2 may be connected to the first node N1. The first terminal and the second terminal of the second transistor T2 may be different terminals. For example, in case that the first terminal is a source electrode, the second terminal may be a drain electrode. A gate electrode of the second transistor T2 may be connected to the i-th scan line Si.

The second transistor T2 may be turned on in case that a scan signal of a voltage at which the second transistor T2 may be turned on is supplied from the i-th scan line Si, to electrically connect the j-th data line Dj and the first node N1. A data signal of a corresponding frame may be supplied to the j-th data line Dj, and thus the data signal may be transferred to the first node N1. The data signal transferred to the first node N1 may be charged in the storage capacitor Cst.

The storage capacitor Cst may charge a voltage corresponding to the data signal supplied to the first node N1 and maintain the charged voltage until a data signal of a next frame is supplied.

FIG. 2 illustrates that the pixel circuit PXC includes the second transistor T2 for transferring the data signal into the pixel PXL, the storage capacitor Cst for storing the data signal, and the first transistor T1 for supplying the driving current corresponding to the data signal to the light emitting element LD, but the disclosure is not necessarily limited thereto, and a structure of the pixel circuit PXC may be variously modified and implemented. For example, the pixel circuit PXC may further include other circuit elements such as at least one transistor element such as a transistor element for compensating for a threshold voltage of the first transistor T1, a transistor element for initializing the first node N1, a transistor element for controlling the emission time of the light emitting elements LD, and/or a boosting capacitor for boosting the voltage of the first node N1. The first and second transistors T1 and T2 of the pixel circuit PXC are not limited to those illustrated in FIG. 2 and may be variously changed to an NMOS or a PMOS.

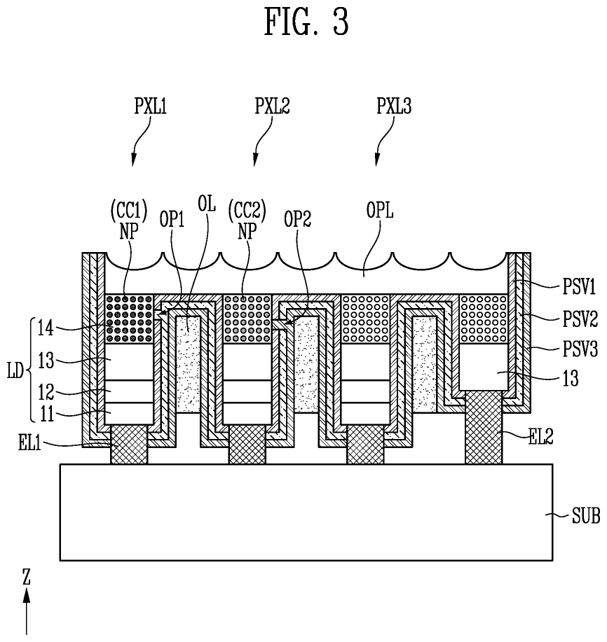

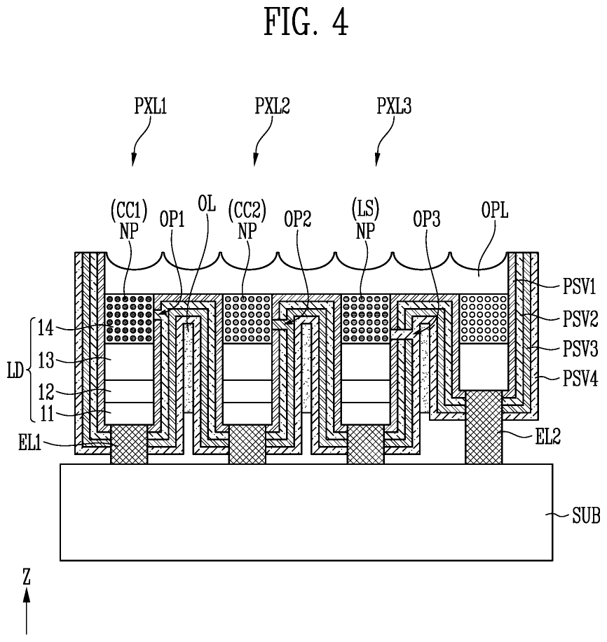

FIGS. 3 and 4 are schematic cross-sectional views illustrating a pixel according to an embodiment.

FIGS. 3 and 4 schematically show a cross-sectional structure of the first pixel PXL1, the second pixel PXL2, and the third pixel PXL3 adjacent to each other.

Referring to FIGS. 3 and 4, a pixel PXL and a display device including the pixel PXL according to an embodiment may include a substrate SUB, the light emitting elements LD disposed on the substrate SUB, and an optical pattern layer OPL disposed on the light emitting elements LD.

The substrate SUB may be a driving substrate including a circuit element and the like including transistors configuring the pixel circuit PXC of FIG. 2 of each pixel PXL.

The light emitting elements LD may include a first semiconductor layer 11, an active layer 12, a second semiconductor layer 13, and a porous layer 14.

The first semiconductor layer 11, the active layer 12, the second semiconductor layer 13, and the porous layer 14 may be sequentially stacked in a third direction (Z-axis direction) on the substrate SUB.

The first semiconductor layer 11 may include at least one p-type semiconductor layer. For example, the first semiconductor layer 11 may include a semiconductor material such as GaN, InGaN, InAlGaN, AlGaN, AlN, AlGaAs, GaAsP, AlGaInP, or GaP, and may include a p-type semiconductor layer doped with a first conductive dopant (or a p-type dopant) such as Mg, Zn, Ca, Sr, or Ba. For example, the first semiconductor layer 11 may include a GaN semiconductor material doped with the first conductive dopant (or the p-type dopant), but is not necessarily limited thereto, and various other materials may configure the first semiconductor layer 11.

The first semiconductor layer 11 may be electrically connected to an area of the substrate SUB. For example, the first electrode EL1 may be disposed on the first semiconductor layer 11, and the first semiconductor layer 11 may be electrically connected to the substrate SUB through the first electrode EL1. According to an embodiment, a first connection layer may be further disposed between the first electrode EL1 and the substrate SUB. As the first electrode EL1 and the substrate SUB are bonded by the first connection layer, the first semiconductor layer 11 and the substrate SUB may be coupled. The first connection layer may include a metal or a metal oxide. For example, the first connection layer may include copper (Cu), gold (Au), chromium (Cr), titanium (Ti), aluminum (Al), nickel (Ni), indium tin oxide (ITO), an oxide, an alloy thereof, or the like, but is not necessarily limited thereto.

The active layer 12 may be disposed between the first semiconductor layer 11 and the second semiconductor layer 13. The active layer 12 may include one of a single well structure, a multi-well structure, a single quantum well structure, a multi-quantum well (MQW) structure, a quantum dot structure, and a quantum line structure, but is not necessarily limited thereto. The active layer 12 may include GaN, InGaN, InAlGaN, AlGaN, AlN, AlGaAs, GaAsP, AlGaInP, or GaP, and various other materials may configure the active layer 12.

In case that a signal (or voltage) is applied to each end of the light emitting element LD, the light emitting element LD may emit light as an electron-hole pair is coupled in the active layer 12 of the light emitting element LD. By controlling emission of each light emitting element LD using such a principle, the light emitting element LD may be used as a light source of various light emitting devices including the pixel PXL of the display device.

According to an embodiment, an electron blocking layer may be further disposed between the active layer 12 and the first semiconductor layer 11. The electron blocking layer may block a flow of an electron supplied from the second semiconductor layer 13 to the first semiconductor layer 11, thereby increasing an electron-hole recombination probability in the active layer 12. An energy band gap of the electron blocking layer may be greater than an energy band gap of the active layer 12 and/or the first semiconductor layer 11, but is not necessarily limited thereto.

According to an embodiment, super lattice layers (SLs) may be further disposed between the active layer 12 and the second semiconductor layer 13. The super lattice layer may relieve stress of the active layer 12 and the second semiconductor layer 13 to improve quality of the light emitting elements LD. The super lattice layer may be formed in a structure in which InGaN and GaN are alternately stacked each other, but is not necessarily limited thereto.

The second semiconductor layer 13 may be disposed on the active layer 12 and may include a semiconductor layer of a type different from a semiconductor layer type of the first semiconductor layer 11. In an embodiment, the second semiconductor layer 13 may include at least one n-type semiconductor layer. For example, the second semiconductor layer 13 may include a semiconductor material such as GaN, InGaN, InAlGaN, AlGaN, AlN, AlGaAs, GaAsP, AlGaInP, or GaP, and may be an n-type semiconductor layer doped with a second conductive dopant (or an n-type dopant) such as Si, Ge, or Sn. For example, the second semiconductor layer 13 may include a GaN semiconductor material doped with the second conductive dopant (or the n-type dopant). However, a material configuring the second semiconductor layer 13 is not limited thereto, and various other materials may configure the second semiconductor layer 13.

The second semiconductor layer 13 may be electrically connected to another area of the substrate SUB. For example, the second electrode EL2 may be disposed on the second semiconductor layer 13, and the second semiconductor layer 13 may be electrically connected to the substrate SUB through the second electrode EL2. According to an embodiment, a second connection layer may be further disposed between the second electrode EL2 and the substrate SUB. As the second electrode EL2 and the substrate SUB are bonded by the second connection layer, the second semiconductor layer 13 and the substrate SUB may be coupled. The second connection layer may include a metal or a metal oxide. For example, the second connection layer may include copper (Cu), gold (Au), chromium (Cr), titanium (Ti), aluminum (Al), nickel (Ni), indium tin oxide (ITO), an oxide, an alloy thereof, or the like, but is not necessarily limited thereto.

The porous layer 14 may be disposed on the second semiconductor layer 13. For example, the porous layer 14 may be disposed (e.g., directly disposed) on the second semiconductor layer 13. The porous layer 14 and the second semiconductor layer 13 may include a same material, but is not necessarily limited thereto. For example, the porous layer 14 may include at least one n-type semiconductor layer. For example, the porous layer 14 may include a semiconductor material such as GaN, InGaN, InAlGaN, AlGaN, or AlN, and may be an n-type semiconductor layer doped with the second conductive dopant (or the n-type dopant) such as Si, Ge, or Sn. For example, the porous layer 14 may include a GaN semiconductor material doped with the second conductive dopant (or the n-type dopant). However, a material configuring the porous layer 14 is not limited thereto, and various other materials may configure the porous layer 14.

The porous layer 14 may include multiple pores NP. The pore NP of the porous layer 14 may be a nano-scale (or may have a nano size) pore NP formed through electrochemical etching, but is not necessarily limited thereto.

The porous layer 14 may improve light emission efficiency by scattering light emitted from the active layer 12. For example, the porous layer 14 may function as a scattering layer. As described above, in case that the porous layer 14 is included in the light emitting elements LD, a scattering layer separately provided in the pixel PXL may be omitted, thereby simplifying a manufacturing process and reducing a cost.

The pore NP of the porous layer 14 may include color conversion materials CC1 and CC2 and/or a scattering body LS. For example, referring to FIG. 3, the porous layer 14 of the light emitting element LD of the first pixel PXL1 may include a first color conversion material CC1, and the porous layer 14 of the light emitting element LD of the second pixel PXL2 may include a second color conversion material CC2.

The first color conversion material CC1 may be disposed in the pore NP of the porous layer 14 of the light emitting element LD of the first pixel PXL1. In case that the first pixel PXL1 is a red pixel, the first color conversion material CC1 may include a first quantum dot that converts blue light into red light. The first quantum dot may absorb the blue light and emit the red light by shifting a wavelength according to an energy transition. In case that the first pixel PXL1 is a pixel of another color, the first color conversion material CC1 may include a first quantum dot corresponding to the color of the first pixel PXL1.

The second color conversion material CC2 may be disposed in the pore NP of the porous layer 14 of the light emitting element LD of the second pixel PXL2. In case that the second pixel PXL2 is a green pixel, the second color conversion material CC2 may include a second quantum dot that converts blue light into green light. The second quantum dot may absorb the blue light and emit the green light by shifting a wavelength according to an energy transition. In case that the second pixel PXL2 is a pixel of another color, the second color conversion material CC2 may include a second quantum dot corresponding to the color of the second pixel PXL2.

An absorption coefficient of the first quantum dot and the second quantum dot may be increased by causing the blue light having a relatively short wavelength in visible light area to be incident to each of the first quantum dot and the second quantum dot. Accordingly, efficiency of light emitted from the first pixel PXL1 and the second pixel PXL2 may be improved and excellent color reproducibility may be secured.

Referring to FIG. 4, the porous layer 14 of the light emitting element LD of the third pixel PXL3 may include a scattering body LS. The scattering body LS may be disposed in the pore NP of the porous layer 14 of the light emitting element LD of the third pixel PXL3.

The scattering body LS may be provided to efficiently use light of a third color (or blue) emitted from the light emitting element LD. For example, the scattering body LS may include at least one of titanium oxide (TiO₂), barium sulfate (BaSo₄), calcium carbonate (CaCo₃), silicon oxide (SiO₂), silicon nitride (Si₃N₄), aluminum oxide (Al₂O₃), zirconium oxide (ZrO₂), and zinc oxide (ZnO) in order to efficiently use the light emitted from the light emitting element LD, but is not necessarily limited thereto. According to an embodiment, the scattering body LS may be omitted or a transparent polymer may be provided instead of the scattering body LS.

Referring to FIG. 3 again, a first protective layer PSV1 may be disposed on the light emitting elements LD. The first protective layer PSV1 may prevent an electrical short circuit that may occur in case that the active layer 12 contacts a conductive material other than the first and second semiconductor layers 11 and 13. The first protective layer PSV1 may minimize a surface defect of each light emitting element LD to improve a lifespan and light emission efficiency of each light emitting element LD.

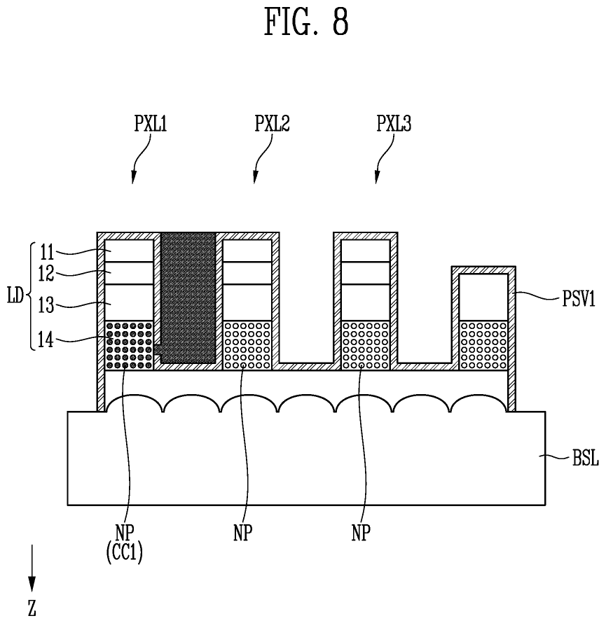

The first protective layer PSV1 may include a first opening OP1 and a second opening OP2 exposing a side surface of the light emitting element LD. For example, the first opening OP1 of the first protective layer PSV1 may expose a side surface of the light emitting element LD of the first pixel PXL1. The first opening OP1 of the first protective layer PSV1 may expose a side surface of the porous layer 14 of the light emitting element LD of the first pixel PXL1. In an embodiment, the first color conversion material CC1 may be injected into the porous layer 14 of the light emitting element LD of the first pixel PXL1 through the first opening OP1 of the first protective layer PSV1. A detailed description thereof is described below with reference to FIG. 8.

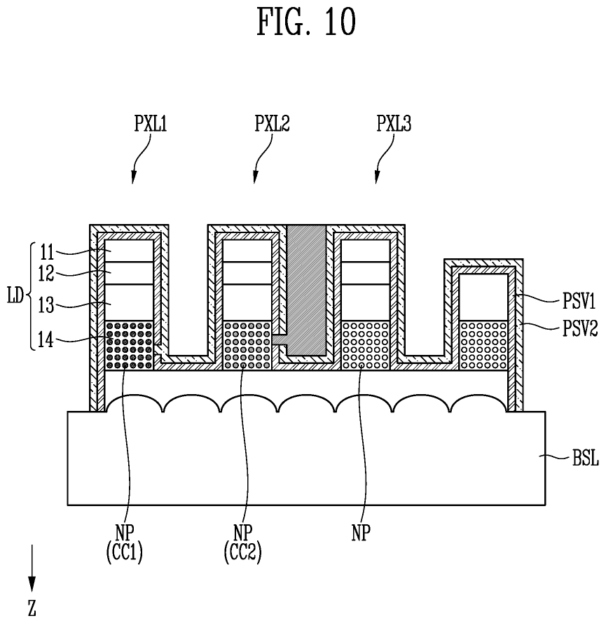

The second opening OP2 of the first protective layer PSV1 may expose a side surface of the light emitting element LD of the second pixel PXL2. The second opening OP2 of the first protective layer PSV1 may expose a side surface of the porous layer 14 of the light emitting element LD of the second pixel PXL2. In an embodiment, the second color conversion material CC2 may be injected into the porous layer 14 of the light emitting element LD of the second pixel PXL2 through the second opening OP2 of the first protective layer PSV1. A detailed description thereof is described below with reference to FIG. 10.

The first protective layer PSV1 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), or the like, but is not necessarily limited thereto.

A second protective layer PSV2 may be disposed on the first protective layer PSV1. The second protective layer PSV2 may cover the first opening OP1 of the first protective layer PSV1. For example, the second protective layer PSV2 may contact the porous layer 14 of the light emitting element LD of the first pixel PXL1 exposed by the first opening OP1 of the first protective layer PSV1.

The second protective layer PSV2 may include a second opening OP2 exposing a side surface of the light emitting element LD of the second pixel PXL2. For example, the second opening OP2 of the second protective layer PSV2 may expose a side surface of the light emitting element LD of the second pixel PXL2. The second opening OP2 of the second protective layer PSV2 may expose a side surface of the porous layer 14 of the light emitting element LD of the second pixel PXL2. In an embodiment, the second color conversion material CC2 may be injected into the porous layer 14 of the light emitting element LD of the second pixel PXL2 through the second opening OP2 of the second protective layer PSV2. A detailed description thereof is described below with reference to FIG. 10.

The second protective layer PSV2 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), or the like, but is not necessarily limited thereto.

A third protective layer PSV3 may be disposed on the second protective layer PSV2. The third protective layer PSV3 may cover the second opening OP2 of the first protective layer PSV1 and the second protective layer PSV2. For example, the third protective layer PSV3 may contact the porous layer 14 of the light emitting element LD of the second pixel PXL2 exposed by the second openings OP2 of the first protective layer PSV1 and the second protective layer PSV2.

The third protective layer PSV3 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), or the like, but is not necessarily limited thereto.

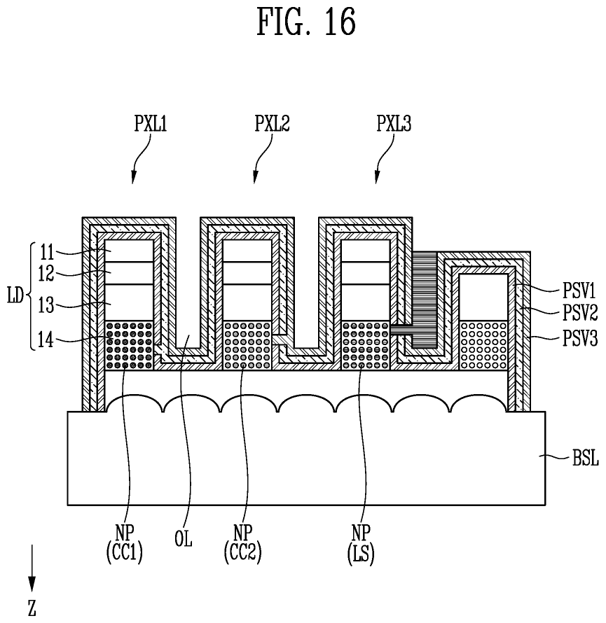

Referring to FIG. 4, the first protective layer PSV1, the second protective layer PSV2, and the third protective layer PSV3 may include a third opening OP3 exposing a side surface of the light emitting element LD of the third pixel PXL3. For example, the third opening OP3 of the first protective layer PSV1, the second protective layer PSV2, and the third protective layer PSV3 may expose a side surface of the light emitting element LD of the third pixel PXL3. The third opening OP3 of the first protective layer PSV1, the second protective layer PSV2, and the third protective layer PSV3 may expose a side surface of the porous layer 14 of the light emitting element LD of the third pixel PXL3. In an embodiment, the scattering body LS may be injected into the porous layer 14 of the light emitting element LD of the third pixel PXL3 through the third opening OP3 of the first protective layer PSV1, the second protective layer PSV2, and the third protective layer PSV3. A detailed description thereof is described below with reference to FIG. 16.

A fourth protective layer PSV4 may be disposed on the third protective layer PSV3. The fourth protective layer PSV4 may cover the third opening OP3 of the first protective layer PSV1, the second protective layer PSV2, and the third protective layer PSV3. For example, the fourth protective layer PSV4 may contact the porous layer 14 of the light emitting element LD of the third pixel PXL3 exposed by the third opening OP3 of the first protective layer PSV1, the second protective layer PSV2, and the third protective layer PSV3.

The fourth protective layer PSV4 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), or the like, but is not necessarily limited thereto.

The first protective layer PSV1, the second protective layer PSV2, the third protective layer PSV3, and/or the fourth protective layer PSV4 may be partially removed to expose an upper surface of the light emitting elements LD. For example, the first protective layer PSV1, the second protective layer PSV2, the third protective layer PSV3, and/or the fourth protective layer PSV4 may be partially removed to expose the first semiconductor layer 11 or the second semiconductor layer 13 of the light emitting elements LD.

According to the above-described embodiment, the color conversion materials CC1 and CC2 or the scattering body LS may be injected into the porous layer 14 through the openings OP1, OP2, and OP3 of the protective layers PSV1, PSV2, and PSV3 exposing the side surface of the porous layer 14 of the light emitting element LD. Accordingly, since a process of etching a layer (for example, an undoped GaN layer) formed on the porous layer 14 to inject the color conversion materials CC1 and CC2 or the scattering body LS into the porous layer 14 may be omitted, a manufacturing process may be simplified and a robust chip may be manufactured.

An organic layer OL may be disposed between the light emitting elements LD. The organic layer OL may be formed between the light emitting elements LD and serve to fix the light emitting elements LD. The organic layer OL may include an organic material such as an acrylate resin, an epoxy resin, a phenolic resin, a polyamide resin, a polyimide resin, a polyester resin, a polyphenylenesulfides resin, or benzocyclobutene (BCB), but is not necessarily limited thereto.

The optical pattern layer OPL may be disposed on the light emitting elements LD. The optical pattern layer OPL may be disposed (e.g., directly disposed) on the porous layer 14. The optical pattern layer OPL may include undoped GaN, InGaN, InAlGaN, AlGaN, AlN, AlGaAs, GaAsP, AlGaInP, GaP, or the like, but is not necessarily limited thereto.

In an embodiment, the optical pattern layer OPL may be formed by forming the light emitting element LD by applying a patterned sapphire substrate (PSS). For example, an upper surface of the optical pattern layer OPL may be separated from the PSS and may have a shape according to a pattern shape of the PSS. For example, the optical pattern layer OPL may have a hemispherical pattern, but is not necessarily limited thereto. Light extraction efficiency may be improved by forming the optical pattern layer OPL having a high refractive index pattern on the porous layer 14 by forming the light emitting element LD using the PSS.

According to the above-described embodiment, the manufacturing process may be simplified by injecting the color conversion materials CC1 and CC2 or the scattering body LS into the porous layer 14 through the openings OP1, OP2, and OP3 of the protective layers PSV1, PSV2, and PSV3 exposing the side surface of the porous layer 14 of the light emitting element LD, and light extraction efficiency may be improved by forming the optical pattern layer OPL on the porous layer 14.

A method of manufacturing the display device according to the above-described embodiment is described.

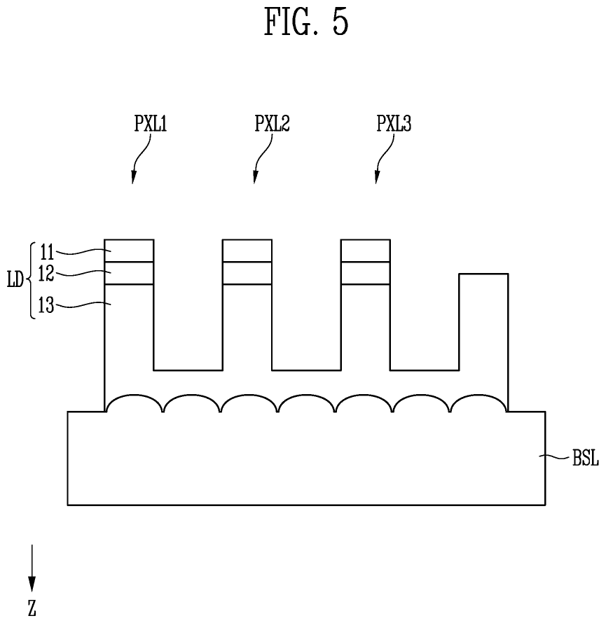

FIGS. 5 to 14 are schematic cross-sectional views for each process step of a method of manufacturing a display device according to an embodiment. FIGS. 5 to 14 are schematic cross-sectional views illustrating a method of manufacturing the display device of FIG. 3, and substantially the same components as those in FIG. 3 are denoted by the same reference numerals and a detailed description is omitted.

Referring to FIG. 5, a base layer BSL may be prepared, and the first semiconductor layer 11, the active layer 12, and the second semiconductor layer 13 of the light emitting element LD may be formed on the base layer BSL. The base layer BSL may be a PSS, but is not necessarily limited thereto. The first semiconductor layer 11, the active layer 12, and the second semiconductor layer 13 may be formed by growing a seed crystal by an epitaxial method, but are not necessarily limited thereto.

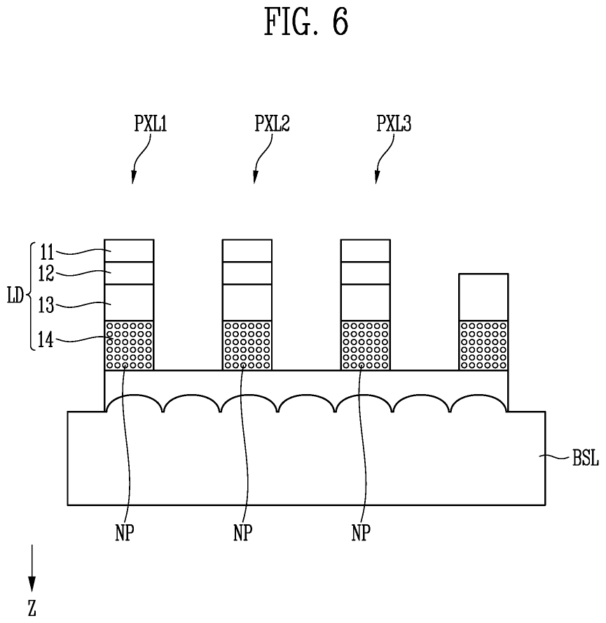

Referring to FIG. 6, the second semiconductor layer 13 may be etched to form the porous layer 14. For example, the pore NP of the nano scale of the porous layer 14 may be formed by electrochemically etching the second semiconductor layer 13. In a process of electrochemically etching the second semiconductor layer 13, a size, a shape, and a distribution of the pore NP of the porous layer 14 may be controlled according to an etchant, a voltage, and/or a doping concentration.

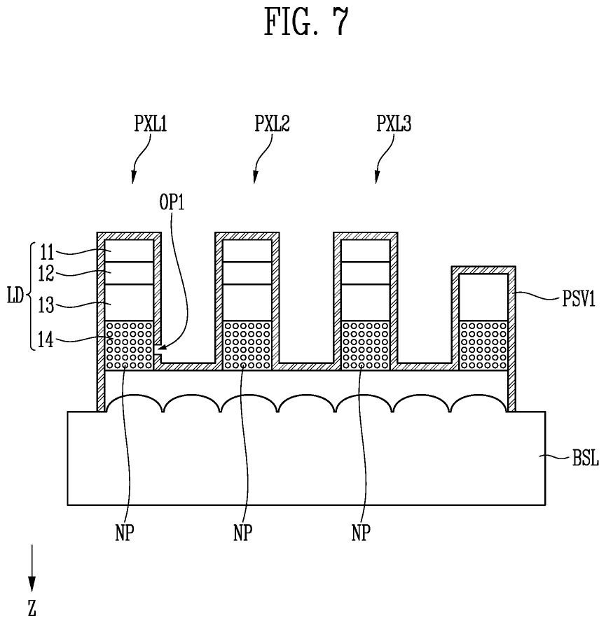

Referring to FIG. 7, the first protective layer PSV1 may be formed on the light emitting element LD. The first protective layer PSV1 may be formed over an entire area of the first to third pixels PXL1, PXL2, and PXL3. A portion of the first protective layer PSV1 may be etched to expose a side surface of the light emitting element LD. For example, the first protective layer PSV1 may include the first opening OP1 exposing the side surface of the porous layer 14 of the light emitting element LD of the first pixel PXL1.

Referring to FIG. 8, the first color conversion material CC1 may be injected into the porous layer 14 of the light emitting element LD of the first pixel PXL1. The first color conversion material CC1 may be injected into the pore NP of the porous layer 14 of the first pixel PXL1 through the first opening OP1 of the first protective layer PSV1. The first color conversion material CC1 may be injected by an inkjet process or spin coating, but is not necessarily limited thereto.

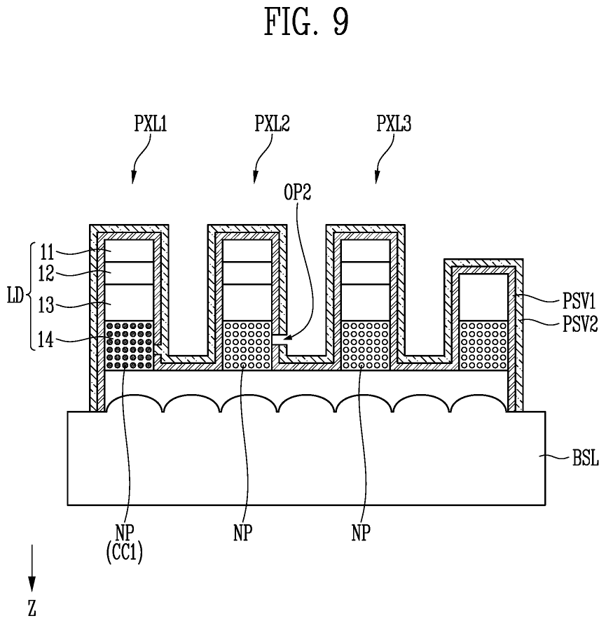

Referring to FIG. 9, the second protective layer PSV2 may be formed on the first protective layer PSV1. The second protective layer PSV2 may be formed over an entire area of the first to third pixels PXL1, PXL2, and PXL3. The second protective layer PSV2 may cover the first opening OP1 of the first protective layer PSV1. For example, the second protective layer PSV2 may cover the porous layer 14 of the light emitting element LD of the first pixel PXL1 exposed by the first opening OP1 of the first protective layer PSV1.

A portion of the second protective layer PSV2 and a portion of the first protective layer PSV1 may be etched to expose a side surface of the light emitting element LD. For example, the second protective layer PSV2 and the first protective layer PSV1 may include the second opening OP2 exposing the side surface of the porous layer 14 of the light emitting element LD of the second pixel PXL2.

Referring to FIG. 10, the second color conversion material CC2 may be injected into the porous layer 14 of the light emitting element LD of the second pixel PXL2. The second color conversion material CC2 may be injected into the pore NP of the porous layer 14 of the second pixel PXL2 through the second opening OP2 of the second protective layer PSV2 and the first protective layer PSV1. The second color conversion material CC2 may be injected by an inkjet process or spin coating, but is not necessarily limited thereto. As described above, as the color conversion materials CC1 and CC2 may be injected into the porous layer 14 through the openings OP1 and OP2 of the protective layers PSV1 and PSV2 exposing the side surface of the porous layer 14 of the light emitting element LD, since a process of etching a layer on the porous layer 14 may be omitted, the manufacturing process may be simplified and a robust light emitting element LD chip may be manufactured as described above.

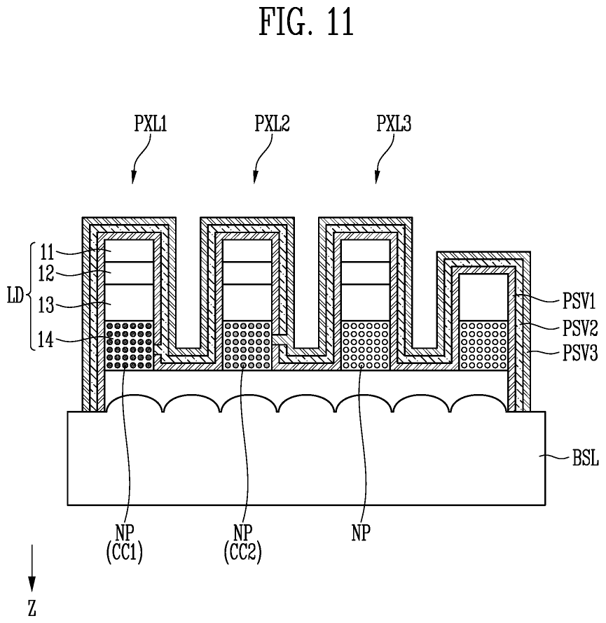

Referring to FIG. 11, the third protective layer PSV3 may be formed on the second protective layer PSV2. The third protective layer PSV3 may be formed over an entire area of the first to third pixels PXL1, PXL2, and PXL3. The third protective layer PSV3 may cover the second opening OP2 of the second protective layer PSV2 and the first protective layer PSV1. For example, the third protective layer PSV3 may cover the porous layer 14 of the light emitting element LD of the second pixel PXL2 exposed by the second opening OP2 of the second protective layer PSV2 and the first protective layer PSV1.

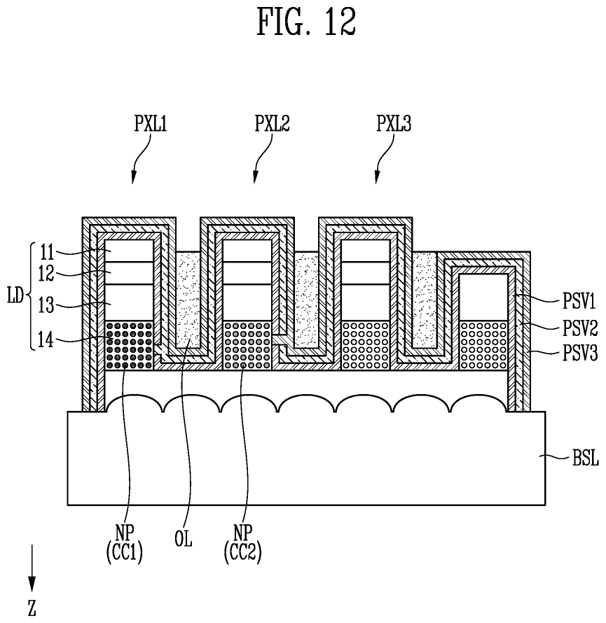

Referring to FIG. 12, the organic layer OL may be formed between the light emitting elements LD. The organic layer OL may be formed (e.g., directly formed) on the third protective layer PSV3.

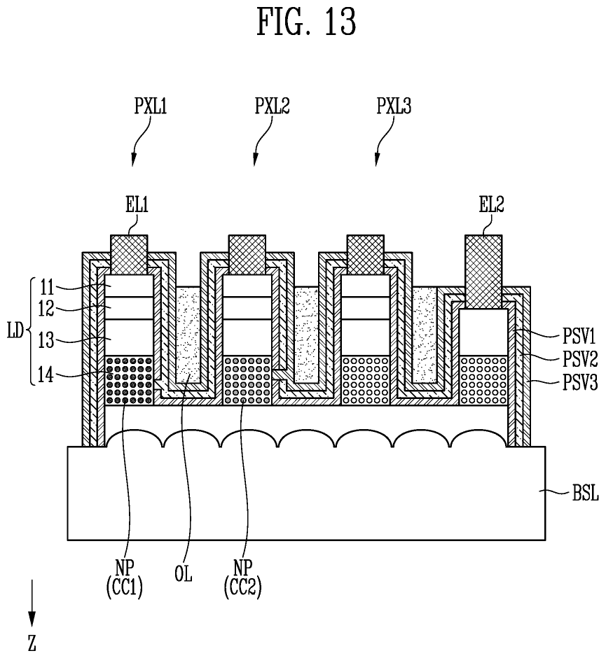

Referring to FIG. 13, the first electrode EL1 and the second electrode EL2 may be formed on the light emitting element LD. A portion of the first protective layer PSV1, a portion of the second protective layer PSV2, and a portion of the third protective layer PSV3 may be removed to expose a surface of the first semiconductor layer 11 or the second semiconductor layer 13 of the light emitting element LD. The first electrode EL1 may be formed on the first semiconductor layer 11 exposed by the first protective layer PSV1, the second protective layer PSV2, and the third protective layer PSV3. The second electrode EL2 may be formed on the second semiconductor layer 13 exposed by the first protective layer PSV1, the second protective layer PSV2, and the third protective layer PSV3.

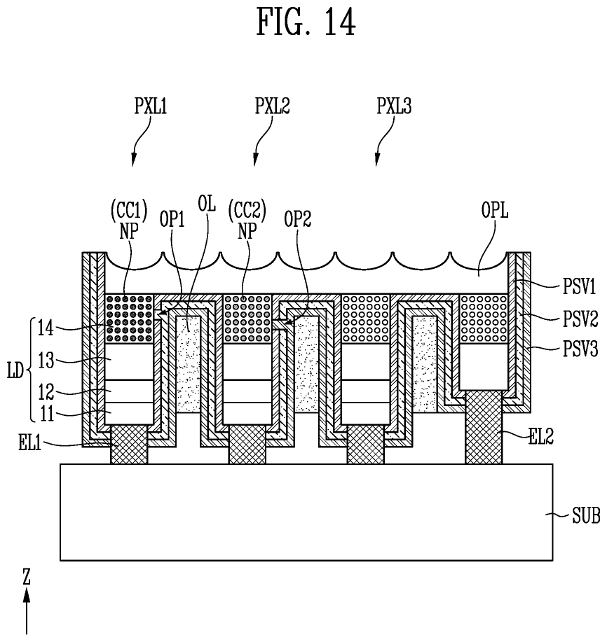

Referring to FIG. 14, the light emitting element LD may be coupled to the substrate SUB. The substrate SUB may be a driving substrate including a circuit element and the like including transistors configuring the pixel circuit PXC of FIG. 2 of each pixel PXL. The first semiconductor layer 11 of the light emitting element LD may be electrically connected to an area of the substrate SUB through the first electrode EL1. The second semiconductor layer 13 of the light emitting element LD may be electrically connected to another area of the substrate SUB through the second electrode EL2.

After coupling the light emitting element LD to the substrate SUB, the base layer BSL may be separated. In a process of separating the base layer BSL, the optical pattern layer OPL may be formed on the porous layer 14. For example, in case that the base layer BSL includes a pattern (predetermined or selectable pattern) as a PSS, an upper surface of the optical pattern layer OPL separated from the base layer BSL may have a pattern shape according to the pattern shape of the base layer BSL. For example, the optical pattern layer OPL may have a hemispherical pattern, but is not necessarily limited thereto. As described above, the light extraction efficiency may be improved by forming the optical pattern layer OPL on the porous layer 14 by forming the light emitting element LD by applying the PSS to the base layer BSL.

Hereinafter, another embodiment is described. In the following embodiment, substantially the same configurations as previously described configurations are denoted by the same reference numerals and a detailed description is omitted or simplified.

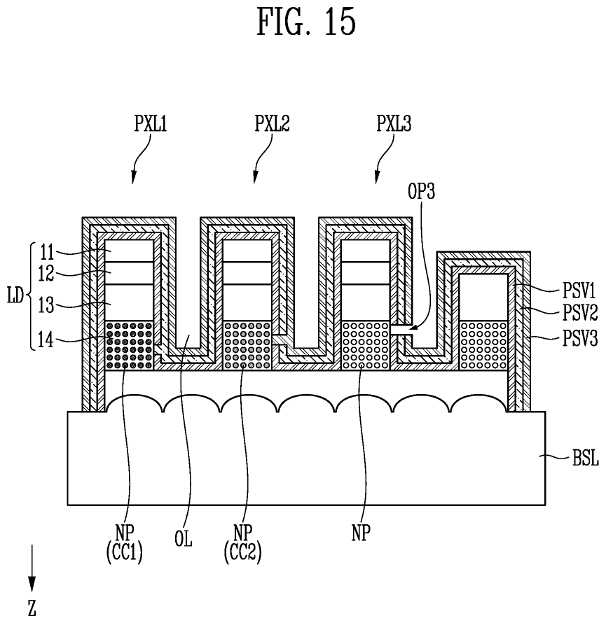

FIGS. 15 to 18 are schematic cross-sectional views for each process step of a method of manufacturing a display device according to an embodiment. FIGS. 15 to 18 are schematic cross-sectional views illustrating a method of manufacturing the display device of FIG. 4. Substantially the same components as those in FIG. 4 are denoted by the same reference numerals and a detailed description is omitted.

Referring to FIG. 15, the third protective layer PSV3 may be formed on the second protective layer PSV2. Since a process step of forming the second protective layer PSV2 and injecting the second color conversion material CC2 is described with reference to FIGS. 5 to 10, an overlapping content is omitted.

The third protective layer PSV3 may be formed over an entire area of the first to third pixels PXL1, PXL2, and PXL3. The third protective layer PSV3 may cover the second opening OP2 of the first protective layer PSV1 and the second protective layer PSV2. For example, the third protective layer PSV3 may cover the porous layer 14 of the light emitting element LD of the second pixel PXL2 exposed by the second openings OP2 of the first protective layer PSV1 and the second protective layer PSV2.

A portion of the third protective layer PSV3, a portion of the second protective layer PSV2, and a portion of the first protective layer PSV1 may be etched to expose the side surface of the light emitting element LD. For example, the third protective layer PSV3, the second protective layer PSV2, and the first protective layer PSV1 may include the third opening OP3 exposing the side surface of the porous layer 14 of the light emitting element LD of the third pixel PXL3.

Referring to FIG. 16, the scattering body LS may be injected into the porous layer 14 of the light emitting element LD of the third pixel PXL3. The scattering body LS may be injected into the pore NP of the porous layer 14 of the third pixel PXL3 through the third opening OP3 of the third protective layer PSV3, the second protective layer PSV2, and the first protective layer PSV1. The scattering body LS may be injected by an inkjet process or spin coating, but is not necessarily limited thereto. As described above, as the color conversion materials CC1 and CC2 or the scattering body LS may be injected into the porous layer 14 through the openings OP1, OP2, and OP3 of the protective layers PSV1, PSV2, and PSV3 exposing the side surface of the porous layer 14 of the light emitting element LD, since a process of etching a layer on the porous layer 14 may be omitted, the manufacturing process may be simplified and a robust light emitting element LD chip may be manufactured.

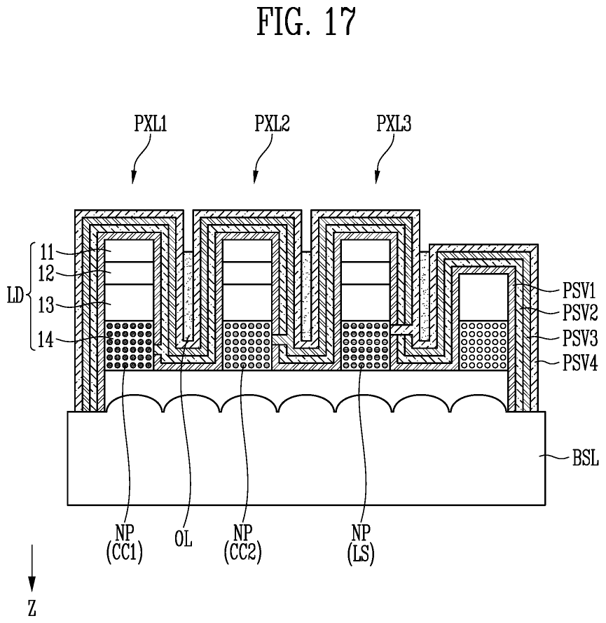

Referring to FIG. 17, the fourth protective layer PSV4 may be formed on the third protective layer PSV3. The fourth protective layer PSV4 may be formed over an entire area of the first to third pixels PXL1, PXL2, and PXL3. The fourth protective layer PSV4 may cover the third opening OP3 of the third protective layer PSV3, the second protective layer PSV2, and the first protective layer PSV1. For example, the fourth protective layer PSV4 may cover the porous layer 14 of the light emitting element LD of the third pixel PXL3 exposed by the third opening OP3 of the third protective layer PSV3, the second protective layer PSV2, and the first protective layer PSV1. The organic layer OL may be formed between the light emitting elements LD. The organic layer OL may be formed (e.g., directly formed) on the fourth protective layer PSV4.

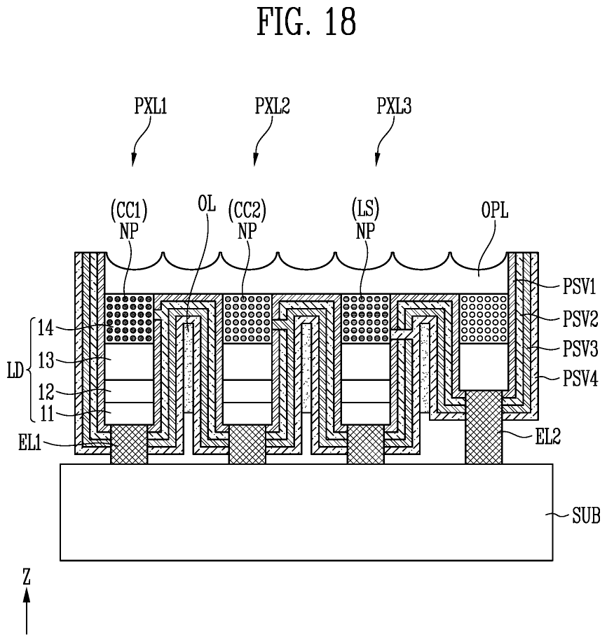

Referring to FIG. 18, the first electrode EL1 and the second electrode EL2 may be formed on the light emitting element LD. A portion of the first protective layer PSV1, a portion of the second protective layer PSV2, a portion of the third protective layer PSV3, and a portion of the fourth protective layer PSV4 may be removed to expose a surface of the first semiconductor layer 11 or the second semiconductor layer 13 of the light emitting element LD. The first electrode EL1 may be formed on the first semiconductor layer 11 exposed by the first protective layer PSV1, the second protective layer PSV2, the third protective layer PSV3, and the fourth protective layer PSV4. The second electrode EL2 may be formed on the second semiconductor layer 13 exposed by the first protective layer PSV1, the second protective layer PSV2, the third protective layer PSV3, and the fourth protective layer PSV4.

The light emitting element LD may be coupled to the substrate SUB. The substrate SUB may be a driving substrate including a circuit element and the like including transistors configuring the pixel circuit PXC of FIG. 2 of each pixel PXL. The first semiconductor layer 11 of the light emitting element LD may be electrically connected to an area of the substrate SUB through the first electrode EL1. The second semiconductor layer 13 of the light emitting element LD may be electrically connected to another area of the substrate SUB through the second electrode EL2.

After coupling the light emitting element LD to the substrate SUB, the base layer BSL may be separated. In a process of separating the base layer BSL, the optical pattern layer OPL may be formed on the porous layer 14. For example, in case that the base layer BSL includes a pattern (predetermined or selectable pattern) as a PSS, an upper surface of the optical pattern layer OPL separated from the base layer BSL may have a pattern shape according to the pattern shape of the base layer BSL. For example, the optical pattern layer OPL may have a hemispherical pattern, but is not necessarily limited thereto. As described above, the light extraction efficiency may be improved by forming the optical pattern layer OPL on the porous layer 14 by forming the light emitting element LD by applying the PSS to the base layer BSL.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
light emitting elements including a porous layer;
a first protective layer disposed on the light emitting elements and including an opening exposing a side surface of the porous layer; and
a second protective layer covering the opening of the first protective layer,
wherein the porous layer includes a color conversion material.

2. The display device according to claim 1, wherein the light emitting elements further include: a first semiconductor layer, a second semiconductor layer, and an active layer disposed between the first semiconductor layer and the second semiconductor layer.

3. The display device according to claim 2, wherein the porous layer and the second semiconductor layer include a same material.

4. The display device according to claim 1, wherein the porous layer includes a pore of a nano scale.

5. The display device according to claim 4, wherein the color conversion material is disposed in the pore.

6. The display device according to claim 1, wherein the second protective layer contacts the porous layer exposed by the opening of the first protective layer.

7. The display device according to claim 1, further comprising:
an organic layer disposed between the light emitting elements.

8. The display device according to claim 7, further comprising:
a third protective layer disposed between the second protective layer and the organic layer.

9. The display device according to claim 1, further comprising:
an optical pattern layer disposed on the light emitting elements.

10. The display device according to claim 9, wherein the optical pattern layer is directly disposed on the porous layer.

11. A display device comprising:
a first light emitting element, a second light emitting element, and a third light emitting element, each including a porous layer;
a first protective layer disposed on the first to third light emitting elements and including a first opening exposing a side surface of the first light emitting element; and
a second protective layer disposed on the first protective layer and including a second opening exposing a side surface of the second light emitting element, wherein
the porous layer of the first light emitting element includes a first color conversion material, and
the porous layer of the second light emitting element includes a second color conversion material.

12. The display device according to claim 11, wherein the second protective layer contacts the porous layer of the first light emitting element exposed by the first opening of the first protective layer.

13. The display device according to claim 11, further comprising:
a third protective layer disposed on the second protective layer.

14. The display device according to claim 13, wherein the third protective layer contacts the porous layer of the second light emitting element exposed by the second opening of the second protective layer.

15. The display device according to claim 11, further comprising:
an organic layer disposed between the first to third light emitting elements.

16. The display device according to claim 11, wherein the porous layer of the third light emitting element includes a scattering body.

17. The display device according to claim 11, wherein each of the first to third light emitting elements further includes a first semiconductor layer, a second semiconductor layer, and an active layer disposed between the first semiconductor layer and the second semiconductor layer.

18. The display device according to claim 17, further comprising:
an optical pattern layer disposed on the first to third light emitting elements.

19. The display device according to claim 17, wherein the second semiconductor layer is directly disposed on a first surface of the porous layer.

20. The display device according to claim 19, wherein the optical pattern layer is directly disposed on a second surface of the porous layer.
